(19) United States
(12) Patent Application Publication
(10) Pub. No.: US 2026/0269172 A1
(43) Pub. Date: Sep. 10, 2026

(54) APPARATUS AND METHOD FOR TRANSFERRING MODULAR FUNCTIONAL UNITS

(71) Applicant: Carl Zeiss Microscopy GmbH, Jena (DE)

(72) Inventor: Andreas SCHMAUNZ, Oberkochen (DE)

(21) Appl. No.: 19/552,401

(22) Filed: Feb. 27, 2026

(30) Foreign Application Priority Data
Mar. 6, 2025 (DE) 10 2025 108 444.0

(51) Int. Cl. H01J 37/18

(52) U.S. Cl. CPC H01J 37/185

(57) ABSTRACT

A transfer system transfers functional units in a vacuum region of a particle beam microscope. The transfer system comprises a transfer unit, a first functional unit detachably coupled to the transfer unit, and a second functional unit detachably coupled to the transfer unit. Each of the first and second functional units is configured to execute a function. The first functional unit can be arranged within the vacuum region in a first position and in a second position. The first functional unit is transferable from the first position to the second position and vice versa. The second functional unit is arrangeable within the vacuum region in a third position and in a fourth position. The second functional unit is transferable from the third position to the fourth position and vice versa.

### CROSS-REFERENCE TO RELATED APPLICATIONS

This application claims benefit under 35 U.S.C. § 119 to German Application No. 10 2025 108 444.0, filed Mar. 6, 2026. The entire disclosure of this application is incorporated by reference herein.

### FIELD

The disclosure provides a transfer unit for transferring functional units in a vacuum region of a particle beam microscope. The disclosure provides a method of transferring functional units in a vacuum region of a particle beam microscope. The disclosure provides a related particle beam microscope.

### BACKGROUND

In a beam microscope (for example a scanning electron microscope (SEM), an ion microscope (FIB) or an FIB/SEM combination instrument (focused ion beam/scanning electron microscope)), various functional units are often fixedly installed in the sample chamber. A functional unit is understood to mean an assembly that is able to execute a particular function. For example, a detector is a functional unit that is configured to detect electrons and/or ions. Further examples of functional units are gas injection systems (for controlled introduction of process gases) or micromanipulators, with which a microscopic sample to be examined can be held and/or moved in a controlled manner in three-dimensional space.

Because functional units use a certain amount of space within the sample chamber, the number of functional units that can be used on a particle beam microscope can be limited.

In many cases, the sample chamber has a limited number of access points (so-called ports) at which functional units can be arranged. Vacuum conditions generally prevail in the sample chamber during the operation of the particle beam microscope, such that it is often desirable for the functional units and the mounting thereof to meet certain desired properties, and the functional units are typically fixedly installed.

DE 10 2008 045 336 B4 (Dömer et al.) describes a processing system in which a sample can be processed with a laser beam and an electron beam or an ion beam. To this end, a sample can be transported back and forth by a transport apparatus between a first processing location and a second processing location. The transport apparatus remains coupled to a base of a positioning stage.

EP 2 950 324 B1 (Albiez et al.) discloses a rail-guided positioning arm that can be used to position a pressure differential module within the sample chamber in an operating position and a non-operating position. The pressure differential module is fixedly mounted on the positioning arm.

### SUMMARY

Often, it is not reasonably possible for the user to exchange functional units depending on the current microscopic application. For example, such an application-dependent exchange could be considered too time-consuming and often can be carried out only by qualified personnel.

It can be desirable to provide a transfer system for transferring functional units and to design the functional units in such a way that they can be changed without complex mechanical modifications. It would be desirable for the change of functional units to take place without breaking the vacuum in the sample chamber.

The present disclosure proposes a transfer system with which modular functional units within a particle beam microscope that can be exchanged and held at particular positions.

In an aspect, the disclosure provides a transfer system for transferring functional units in a vacuum region of a particle beam microscope. The transfer system comprises a transfer unit and at least two functional units. Each functional unit is configured to execute a function during operation of the particle beam microscope. The transfer system is designed in such a way that a first functional unit is able to be arranged within the vacuum region of the particle beam microscope in a first position and in a second position. The transfer unit is configured to transfer the first functional unit from the first position to the second position and vice versa. The first functional unit is detachably couplable to the transfer unit. The transfer system is designed in such a way that a second functional unit is able to be arranged within the vacuum region of the particle beam microscope in a third position and in a fourth position. The transfer unit is configured to transfer the second functional unit from the third position to the fourth position and vice versa. The second functional unit is detachably couplable to the transfer unit.

In an aspect, the disclosure provides a method for transferring functional units in a vacuum region of a particle beam microscope. The transfer system comprises a transfer unit and at least two functional units, and the functional units each being configured to execute a function. The transfer system is designed in such a way that a first functional unit is able to be arranged within the vacuum region of the particle beam microscope in a first parked position and in a first working position. The transfer system is designed in such a way that a second functional unit is able to be arranged within the vacuum region of the particle beam microscope in a second parked position and in a second working position. The method comprises: providing the functional units in the vacuum region in the respective parked position; detachably coupling the first functional unit to the transfer unit; transferring the first functional unit from the first parked position to the first working position with the aid of the transfer unit; handing over the first functional unit from the transfer unit to the first working position; detachably coupling the second functional unit to the transfer unit; transferring the second functional unit from the second parked position to the second working position with the aid of the transfer unit; handing over the second functional unit from the transfer unit to the second working position; and executing the function of the functional units.

In an aspect, the disclosure provides a particle beam microscope, comprising: a sample stage for receiving a sample holder, the sample holder being configured to hold a microscopic sample; a particle beam source for generating a particle beam which is able to be directed at a microscopic sample held by the sample holder; a sample chamber which encloses a vacuum region within the particle beam microscope; and a transfer system for transferring functional units in the vacuum region of the particle beam microscope. The transfer system comprises a transfer unit and at least two functional units. Each functional units is configured to execute a function. The transfer system is designed in such a way that a first functional unit is able to be arranged within the vacuum region of the particle beam microscope in a first position and in a second position. The transfer unit is configured to transfer the first functional unit from the first position to the second position and vice versa. The first functional unit is detachably couplable to the transfer unit. The transfer system is designed in such a way that a second functional unit is able to be arranged within the vacuum region of the particle beam microscope in a third position and in a fourth position. The transfer unit is configured to transfer the second functional unit from the third position to the fourth position and vice versa. The second functional unit is detachably couplable to the transfer unit.

The disclosure provides a modular system of functional units in which the functional units can be reversibly arranged at various positions inside a particle beam microscope. For transferring the functional units from one position to another, the transfer system can comprise a correspondingly configured transfer unit to which the functional units can be detachably coupled and moved in a targeted manner in the coupled state.

A functional unit is understood to mean an assembly which is configured to execute a particular function during operation of the particle beam microscope, such as a sample holder whose function is to hold a microscopic sample.

A functional unit is able to perform a defined task in sample analysis, sample imaging or sample preparation in the particle beam microscope, and can bring about a particular effect in the running of the operation.

The positions at which a functional unit is able to be arranged can be designed, for example, as a working position and a parked position. At a working position, the function of a functional unit arranged there is able to be performed, whereas this is not the case in a parked position. A parked position is therefore a non-working position.

The positions serve as mechanical interfaces which can be used to arrange the modularly designed functional units in the particle beam microscope. It is conceivable for the positions to be additionally designed as electrical interfaces, in order to control the functional units and/or execute their respective function.

The positions at which the functional units can be arranged may be located on any object or surface located in the vacuum region of a particle beam microscope, for example in the sample chamber, on the SEM column, on the movable sample stage, on a sample holder or even on the microscopic sample itself.

The vacuum region is understood to mean a three-dimensional space in which vacuum conditions prevail during operation, optionally enclosed by a vacuum jacket. The vacuum region usually comprises the sample chamber of the particle beam microscope and a lock chamber potentially arranged on the sample chamber.

Each functional unit is able to be detached from the transfer unit again and handed over to a position. Conversely, a functional unit can be detached from a position and received by the transfer unit. For example, this can be achieved by providing receiving apparatuses, which are compatible with the functional units, at the positions.

All the receiving apparatuses at the positions form a receiving system. It can be desirable for the receiving apparatuses of the receiving system and the functional units to be modular, such that they are compatible with one another. For example, the receiving apparatuses may be designed as identical dovetail connections, such that various functional units in the various positions are interchangeable with one another. Instead of a form-fitting connection, it is conceivable for the receiving apparatus and the functional elements to be able to be connected to one another in a materially bonded or frictional manner. A relevant point here is that it is desirable for the connection to be reversible, i.e. can be detached again.

It is desirable for the transfer system to comprise a functional unit changer which is configured to make available multiple functional units. This can be effected by holding the functional units ready in the functional unit changer in the parked positions.

It has proven to be desirable for the transfer unit to be movable to a rest position, such that it can be arranged in this rest position whenever it is not required for transferring functional units. This can help ensure that the transfer unit does not disrupt further processes during operation of the particle beam microscope.

The functional units may be designed, for example, as active functional units. An active functional unit is understood to mean an assembly that intervenes physically in the running of the operation, for example as a heating element, manipulator, detector (for detecting interaction particles and/or interaction radiation), gas injection system or power supply.

However, the functional units may also be designed as passive units that do not intervene in the running of the operation, such as a temperature sensor.

It can be desirable for the functional units to be designed such that multiple functional units can be connected to one another. The functional units may be of substantially similar or alternatively different design.

The functional units may be designed, for example, as micromanipulators. Micromanipulators are used, for example, in nanoprobing. However, the functional units may also be designed differently, for example as a stop, detector, sensor, sample holder or sample holder modules which can be joined together to form a multi-part sample holder.

Usually, the functional units are intended to be used in the vacuum region of the particle beam microscope. Therefore, it may be desirable for the particle beam microscope to optionally have a lock and/or a transfer shuttle, which can additionally facilitate the handling of various functional units.

A transfer shuttle is understood to mean a compact, separable, transportable lock that can be flanged onto a particle beam microscope during use (i.e. loaded with an object). In an embodiment, the transfer shuttle is designed as an inert shuttle. In this case, there can be a protective gas atmosphere in the object space of the inert shuttle, such that an object received in the object space can be transported under protective gas and delivered to the vacuum region of the particle beam microscope.

Exemplary embodiments of the disclosure are explained below with reference to figures. For the purpose of explaining the components, reference can also be made to the respectively preceding and succeeding description in its entirety.

### BRIEF DESCRIPTION OF THE DRAWINGS

FIGS. 1A-1E show a transfer system in which functional units are designed as micromanipulators.

FIGS. 2A-2E show functional units designed as a sample holder and a sensor.

FIG. 3 shows a variant which differs from FIG. 2 in terms of the design of the electrical connection.

FIGS. 4A-4E show an embodiment which can be used to change pressure stage stops on the objective of a particle beam column.

FIGS. 5A-5B show multiple functional units provided in a functional unit changer. The functional units are stackable on top of one another in the working position, such that they can be reversibly (such as detachably) coupled to one another.

FIGS. 6A-6C shows an embodiment similar to FIGS. 2 and 3 and in which two sample holders are transferred, which interact at the working position.

FIGS. 7A-7R illustrate a multi-part sample holder comprising two modules. FIGS. 7A-7I illustrate the introduction and transfer of a first sample holder module, whereas FIGS. 7J-7R show the introduction and transfer of a second sample holder module and the joining together of the two sample holder modules.

FIG. 8 is a schematic flow chart of a method.

FIG. 9 shows an FIB/SEM combination instrument as an example of a particle beam microscope that can be used to carry out the method according to the disclosure.

### EXEMPLARY EMBODIMENTS

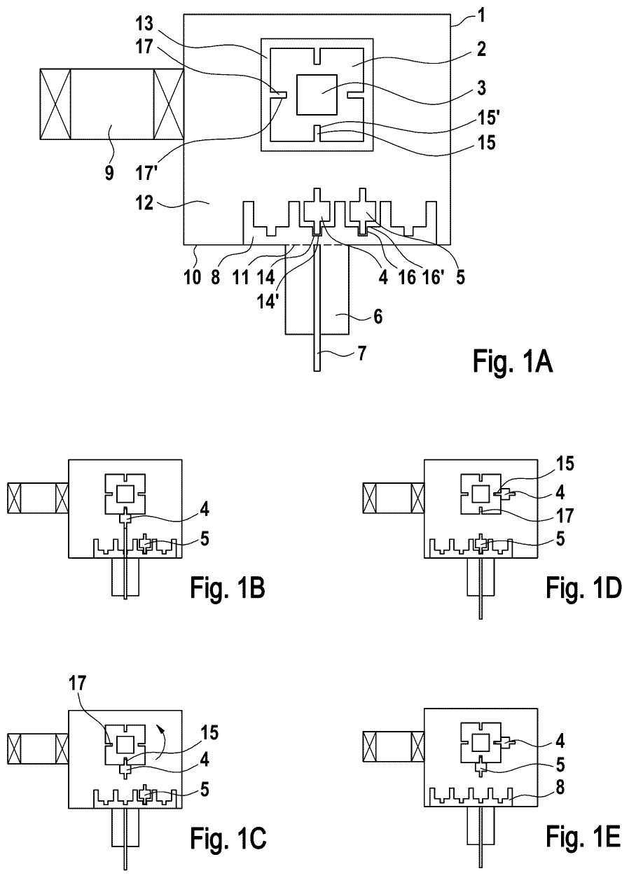

FIGS. 1A-1E show a first exemplary embodiment of the transfer system according to the disclosure. In this application example, it is a matter of arranging multiple micromanipulators 4, 5 on a sample holder 2 inside a sample chamber 1, in order to enable specific sample processing operations such as nanoprobing.

The present disclosure provides a transfer system in the sample chamber 1 of a particle beam microscope, comprising a movable transfer unit 6.

It has proven to be desirable for the transfer unit 6 has an elongate transfer rod 7 which passes through a vacuum seal 11 provided in the wall 10 of the sample chamber, as schematically indicated in FIGS. 1A-1E. A part of the transfer unit 6 is always arranged in the vacuum region 12 of the particle beam microscope and configured to reversibly receive a functional unit.

The transfer system furthermore comprises at least two functional units, in this case two micromanipulators 4, 5, which are provided within the sample chamber 1 (that is to say in the vacuum region). The micromanipulators 4, 5 are each able to be arranged in a first position 14, 16, the parked position, and a second position 15, 17, the working position. A micromanipulator 4, 5 is held in the parked position when it is not in use, whereas the micromanipulator 4, 5 is held in the working position when it is used for sample handling, that is to say executes its function.

FIG. 1A illustrates how the first micromanipulator 4 and the second micromanipulator 5 are held in the respective parked position 14 and 16 by an optional changing apparatus in the form of a functional unit changer 8.

In principle, the micromanipulators 4, 5 are detachably couplable to the transfer unit 6. The respectively coupled micromanipulator 4, 5 can then be transferred from the parked position to a working position by movement of the transfer unit 6, as illustrated in FIG. 1B. In the working position, the respective micromanipulator 4, 5 can be reversibly arranged on the sample holder 2 in order to carry out its function there during handling of the sample 3. For example, the micromanipulator 4, 5 may receive and hold the sample 3. In order to execute this function, the respective micromanipulator 4, 5 is dispensed from the transfer unit 6 to the working position on the sample holder 2.

Both micromanipulators 4, 5 can thus be transferred from a parked position to a working position using the transfer unit 6.

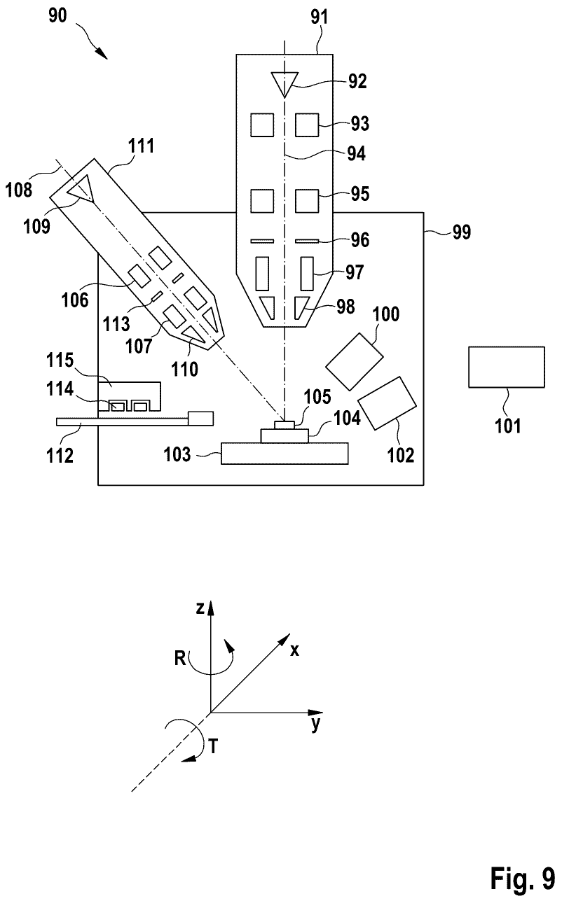

In the case of the second micromanipulator 5, it may be desirable in the present example to arrange the sample holder 2 differently relative to the transfer unit 6 in order to make the working position 17 of the second micromanipulator 5 accessible for transfer. To this end, it is for example possible for the sample stage 13 together with the sample holder 2 to be rotated about a rotation axis R (as described for the particle beam microscope in FIG. 9), as indicated by the arrow in FIG. 1C. This makes it possible for the working position 17 of the second micromanipulator 5 to be accessible for the transfer unit 6 (FIG. 1D), such that the transfer unit can reversibly dispense the second micromanipulator 5 to this working position 17.

When the micromanipulators 4, 5 have been arranged in their working positions 15, 17 in order to execute their function, the transfer unit 6 can be retracted into a rest position, as shown in FIG. 1E. It is thus conceivable for the transfer unit to be positionable in the vicinity of the chamber wall 10, such that the further sample handling or the sample processing are not disrupted by the transfer unit.

Once the work with the micromanipulators has been completed, both micromanipulators can be transferred from the working positions to the transfer unit, since they are detachably couplable. The micromanipulators can then be transferred back to the respective parked position 14, 16 and dispensed there at the parked position.

In principle, it has proven to be desirable for the transfer system to comprise a receiving system having multiple receiving apparatuses 14′, 15′, 16′, 17′. The receiving system is designed in such a way that all the parked positions and all the working positions are each provided with a receiving apparatus 14′, 15′, 16′, 17′ for reversibly receiving a functional unit.

The receiving apparatuses 14′, 15′, 16′, 17′ may be designed, for example, as a form-fitting connection, such as dovetail connections or bayonet closures. However, it is also conceivable for the receiving apparatuses 14′, 15′, 16′, 17′ to be designed differently, for example as a threaded hole, magnet holder or adhesion holder. It is also conceivable for the connection to be effected in a frictional or materially bonded manner. Of relevance here is that the functional units can each be detachably connected to the receiving apparatuses 14′, 15′, 16′, 17′.

This therefore means that the functional units are designed as modules which are compatible with the transfer unit and the receiving apparatuses and can each be reversibly received. This enables flexible transfer and flexible positioning of the functional units.

Therefore, the receiving system of the transfer system in FIGS. 1A-1E is configured in such a way that the first micromanipulator 4 is able to be received in the first parked position 14 by a first receiving apparatus 14′ and in the first working position 15 by a second receiving apparatus 15′.

Furthermore, the receiving system is configured to receive the second micromanipulator 5 in the second parked position 16 by a third receiving apparatus 16′ and in the second working position 17 by an assigned fourth receiving apparatus 17′. In this case, the transfer unit and the micromanipulators are configured in such a way that the micromanipulators are able to be handed over from the respective receiving apparatus to the transfer unit and vice versa.

Furthermore, the transfer system may comprise a functional unit changer 8 which can be used to provide multiple micromanipulators in their respective parked position. The functional unit changer 8 is arranged in the vacuum region 12, i.e. inside the sample chamber 1. The receiving apparatuses which are assigned to the parked positions (in the present example: the first receiving apparatus 14′ and the third receiving apparatus 16′) are integrated in the functional unit changer 8.

It has proven to be particularly desirable for the functional unit changer 8 with the micromanipulators received therein to be introduced into the vacuum region 12 using an optional lock 9, which is arranged on the sample chamber 1, without the vacuum needing to be broken. It is equally conceivable for the sample holder 2 together with the sample 3 to be introduced via the lock 9 into the sample chamber 1.

In principle, the micromanipulators 4, 5 can each be individually transferred from the transfer unit 6 in the manner described. However, it is also conceivable for both micromanipulators 4, 5 to be detachably coupled to the transfer unit 6, transferred and dispensed again at the same time. Furthermore, a transfer system 6 which comprises not only one transfer unit but multiple transfer units is conceivable.

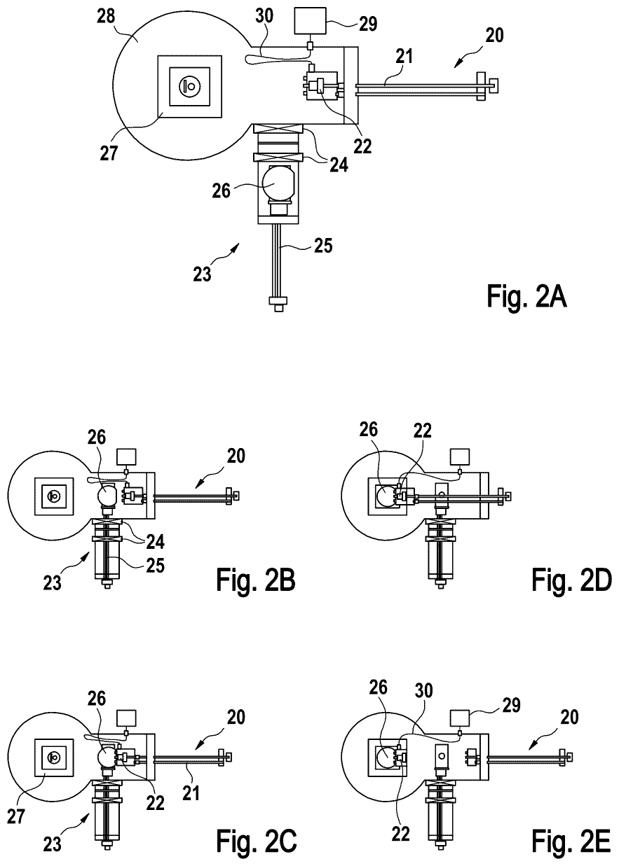

FIGS. 2A-2E show a second embodiment of the transfer system in which the functional units are designed as a sample holder 26 and a sensor 22. The sample holder 26 is configured to receive a sample to be examined (not illustrated). The sensor 22 may be designed, for example, as a temperature sensor in order to monitor the temperature of the sample during a microscopic examination.

It has proven to be desirable for the particle beam microscope to comprise a lock 23. Usually, the lock 23 is flanged to a port of the sample chamber 28. Controllable lock valves 24 can be used to connect the lock space to the volume of the sample chamber 28 or to separate it therefrom. In order for objects or components to be introduced into (or removed from) the sample chamber 28 via the lock 23, the lock 23 usually has a movable lock rod 25.

In this case, it has proven to be desirable for the sample holder 26 to be couplable to the lock rod 25 and able to be handed over to the transfer unit 20 after being introduced by the lock rod 25.

In principle, it is desirable for the functional units (that is to say sensor 22 and sample holder 26) to each be arranged in a parked position during work breaks, as illustrated in FIG. 2A. In the present specific example, the sensor 22 is held in the parked position by the transfer unit 20.

The transfer unit 20 of the transfer system comprises a transfer rod 21 to which the functional units can be detachably coupled.

In order to prepare the microscopic examination, the sample holder 26 can be introduced via the lock 23 using the lock rod 25 through the opened lock valves 24 into the vacuum region of the sample chamber 28 (FIG. 2B) without the vacuum being broken.

The sample holder 26 can then be detachably coupled to the transfer rod 21 of the transfer unit 20 (FIG. 2C), such that both functional units 22, 26 are transferable to their working position on the sample stage 27 by the movement of the transfer unit 20, as shown in FIG. 2D.

Here, as described above, receiving apparatuses can be provided at the parked positions and the working positions, which serve as modular interfaces.

In order to not disrupt the further examinations or operating states of the particle beam microscope, the transfer unit 20 can be retracted from the sample chamber and held in a rest position, as shown in FIG. 2E.

For the handling of the sensor 22, the latter can be connected via a direct cable connection 30 to a controller 29 in order to control or read out the sensor. In the example of FIGS. 2A-2E, the cable connection 30 is arranged on the sensor 22 itself.

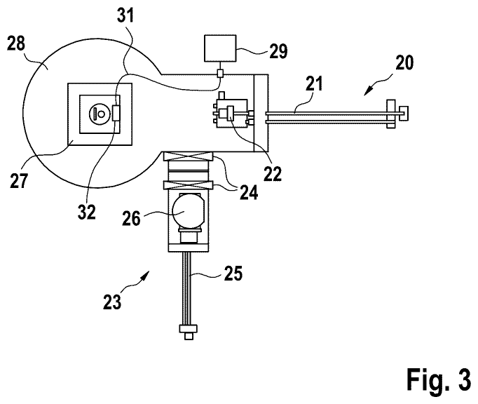

In an alternative variant of the second embodiment shown in FIG. 3, the electrical control of the sensor 22 is designed such that an alternative cable connection 31 is arranged on the sample stage 27, that is to say in the vicinity of the working position of the sensor 22. The interface on the sample stage 27 can provide all the desired electrical connections, such as power supply and signal line.

In a refinement in FIG. 3, the electrical interface is integrated in the receiving apparatus 32 of the working position. As soon as the sensor 22 has been handed over to the receiving apparatus 32, the sensor 22 can be controlled by the controller 29.

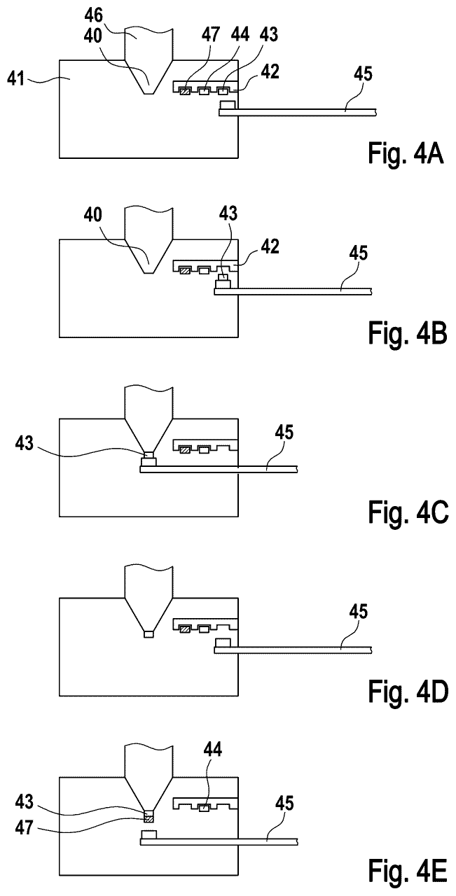

FIGS. 4a-e show a third embodiment which allows improved changing of pressure stage stops on the objective of a particle beam column of a particle beam microscope. In this embodiment, the functional units are designed, inter alia, as pressure stage stops.

Usually, objectives of particle beam microscopes are in the form of a truncated cone, the truncated cone enclosing the optical axis. Often, further assemblies, such as a cap or a pressure stage stop, are arranged adjoining the top surface of the truncated cone. Pressure stage stops have the task of delimiting various pressure zones within a particle beam microscope from one another and at the same time ensuring the optical beam path.

The objective 40 of the particle beam column 46 shown in FIGS. 4A-4E is at least partially arranged in the sample chamber 41 of the particle beam microscope, in which vacuum conditions prevail during operation. Depending on the desired sample application, it is desirable to arrange a pressure stage stop, matched to the sample application, in the end region of the objective (that is to say on the top surface of the truncated cone-shaped objective) in order to ensure that the vacuum region is divided into various pressure regions.

For example, when operating in normal mode, a first pressure stage stop 43 with a relatively large aperture is used, whereas when switching to variable pressure mode (VP mode), a second pressure stage stop 44 with a smaller stop diameter is used. Since the aperture of the second stop 44 has a smaller diameter, the producible field of view is somewhat restricted, but the smaller aperture is used to prevent a pressure increase inside the particle beam column 46.

The transfer system according to the disclosure can be used to facilitate the changing of such pressure stage stops 43, 44. The transfer system comprises a transfer unit 45, and also at least two pressure stage stops 43, 44, which usually have different stop diameters.

The pressure stage stops 43, 44 are held ready in a parked position within the sample chamber or within the vacuum region. This can be achieved using a changing apparatus in the form of a stop changer 42 (FIG. 4A).

Furthermore, the pressure stage stops 43, 44 can be arranged in a working position (FIGS. 4C-4E), the transfer unit 45 carrying out the transfer between the two positions, as described above. In order to enable the transfer, the transfer unit 45 is designed such that the pressure stage stops 43, 44 are detachably couplable to the transfer unit 45.

The transfer system according to the disclosure thus comprises a transfer unit which is configured to transfer the pressure stage stop from a first position to a second position, and from the second position to the first position.

In other words: the transfer device is configured to transfer the pressure stage stop from the parked position to the working position, where the pressure stage stop can execute its function. On the other hand, the transfer unit is also configured to transfer the pressure stage stop from the working position back to the parked position, where the pressure stage stop can be stored.

As already described above, in the exemplary embodiment in FIGS. 4A-4E, receiving apparatuses which allow the modular use of the pressure stage stops 43, 44 may also be provided at the parked and working positions.

Furthermore, it is conceivable for not only identical functional units such as the described pressure stage stops 43, 44, which differ only in terms of the diameter of the apertures, to be transferred. It is also conceivable for the transfer unit to be used to transfer different functional units such as a pressure stage stop and a detector 47 to the working position on the objective 40 (FIG. 4e). The detector 47 may, for example, be a BSD detector (backscattered electron detector), which is usually arranged on the objective 40.

The modular construction of the functional units and of the receiving apparatuses thus makes it possible for, instead of a pressure stage stop or in addition to a pressure stage stop, a further, different functional unit (i.e. a functional unit configured to execute a different function) to be arranged with the aid of the transfer system such that the functional units can execute their respective function in the particle beam microscope.

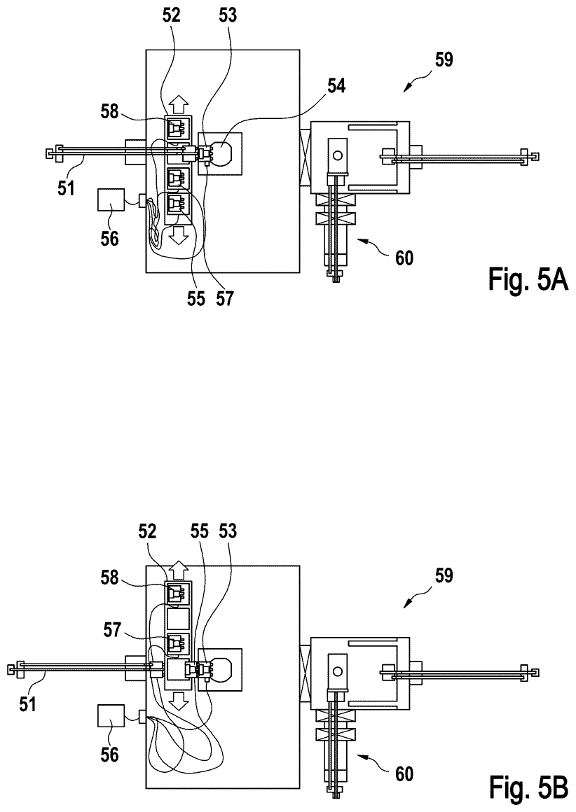

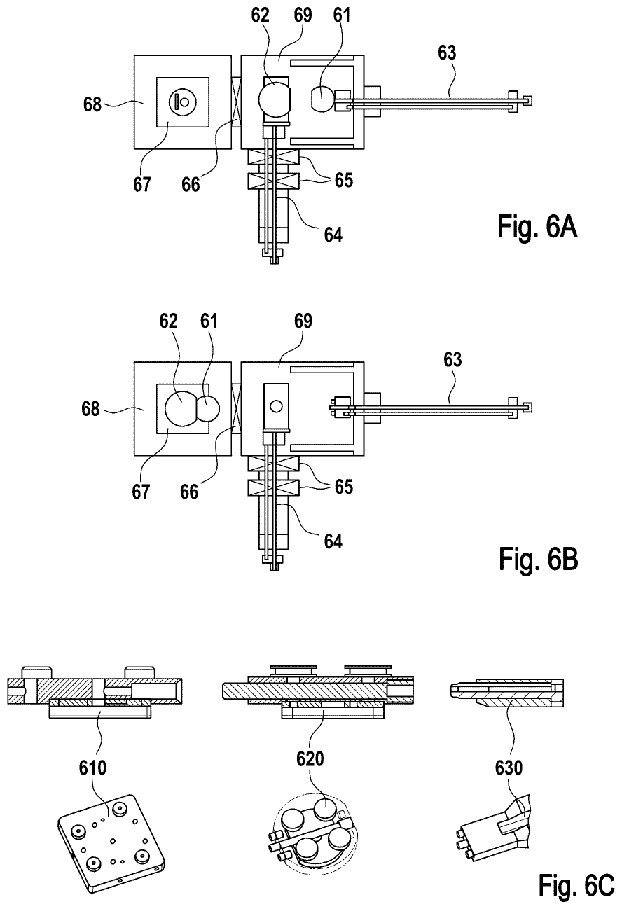

Furthermore, it is conceivable for multiple identical or multiple different functional units to be connected to one another at the working position, that is to say be almost stacked on top of one another, as explained in more detail for FIGS. 5A-5B and FIGS. 6A-6C.

In a further exemplary embodiment shown in FIGS. 5A-5B, multiple functional units 53, 55, 57, 58 (for example micromanipulators and detectors) are provided in a functional unit changer 52 in parked positions.

A first functional unit 53 can be transferred using the transfer unit 51 from the parked position to a working position and dispensed at the working position, as illustrated in FIG. 5A. The working position may be located, for example, on a sample holder 54. The transfer unit 51 is controlled by way of the controller 56.

Then a second functional unit 55 can be transferred from the parked position to the working position (FIG. 5B). Since the first functional unit 53 has a receiving apparatus, the second functional unit 55 can be reversibly coupled to the first functional unit 53. This therefore means that two functional units are able to be mounted on top of one another at the working position, but are also detachable from one another again. This is desirable if there is little space available on the sample holder or generally in the sample chamber.

In addition, it is in principle conceivable for the particle beam microscope to optionally have a lock 59 and/or an inert shuttle 60 (for the introduction of objects under a protective gas atmosphere) (as shown in FIGS. 5A-5B), which additionally facilitates the handling of various functional units.

FIGS. 6A-6C show a further embodiment of the disclosure which is similar to the embodiment in FIGS. 2A-2E and FIG. 3 and in which two sample holders 61, 62 are couplable to one another, such that both sample holders 61, 62 can interact with one another.

This embodiment is desirable, for example, for the preparation of a TEM lamella from a sample block. It is for example possible for the first sample holder 61 to hold the sample block during processing with the focused ion beam (FIB), such that a TEM lamella can be prepared from the sample block and removed. The second sample holder 62 can then provide a specific apparatus in order to receive the removed, very fragile TEM lamella after lift-out.

Often, however, the sample holder combination for this procedure is so large that it cannot be introduced via a lock into the lock chamber 69 or the sample chamber 68 of the particle beam microscope. The disclosure proposed here makes it possible to introduce the sample holders 61, 62 separately into the vacuum region and then arrange them such that both sample holders 61, 62 can execute their respective function and interact during the TEM lamella preparation.

For example, the first sample holder 61 together with the sample block can be introduced, when the inert shuttle valve 65 is open, via the inert shuttle 64 into the lock chamber 69. The second sample holder 62 can be held ready in a parked position inside the lock chamber (FIG. 6A).

With the aid of the transfer unit 63, both sample holders 61, 62 can be transferred via the opened lock valve 66 into the sample chamber 68. There, the sample holders 61, 62 can be transferred and handed over to the adjacent working positions on the sample stage 67 (FIG. 6B). The adjacently arranged sample holders 61, 62 can then interact during sample preparation.

FIG. 6C shows by way of example how two sample holders 610, 620 can be separably connected to one another by a simple mechanism.

In this specific example, the first sample holder 610 is a sample holder with a specific sample receptacle and the second sample holder 620 is a sample holder with a standard sample receptacle.

The transfer rod 630 of the transfer unit 63 is connected to the first sample holder 610. The first sample holder 610 is then moved closer to the second sample holder 620 by movement of the transfer rod 630 and connected thereto.

The transfer rod 630 is then detached from the sample holders again and returned to the rest position.

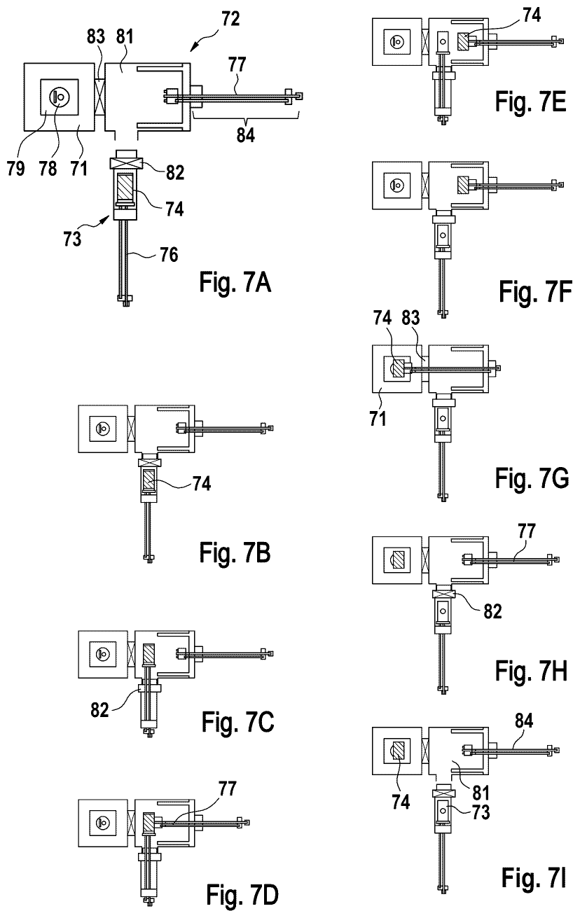

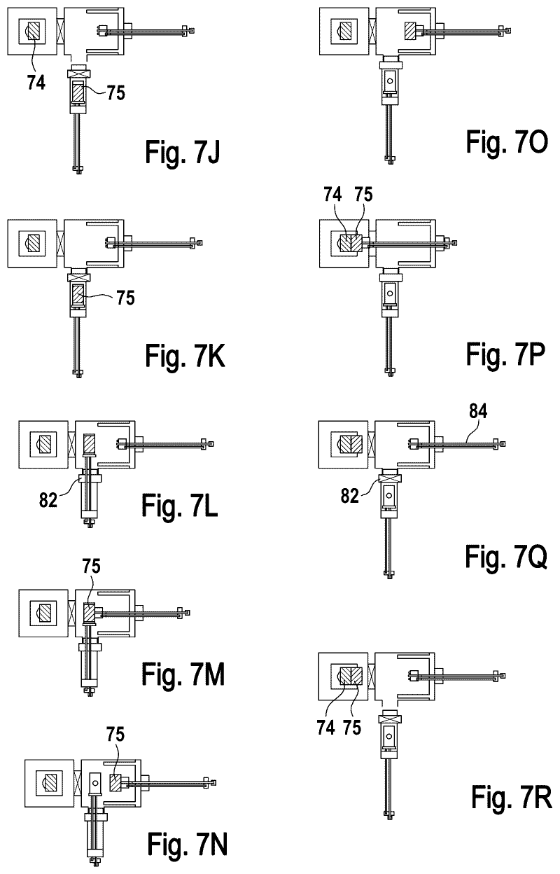

The idea of a multi-part, or modularly designed, sample holder is further developed in the embodiment of the disclosure illustrated in FIGS. 7A-7R. It is namely conceivable for a sample holder to be formed from two modules which are separable from one another and can be used with the aid of the transfer system according to the disclosure.

This means that the sample holder can be disassembled into smaller assemblies that can be easily introduced via an inert shuttle into the vacuum region of a particle beam microscope, which would not be possible in a non-disassembled state due to the size.

FIGS. 7A-7R show how the two sample holder modules 74, 75 are introduced into the vacuum region and joined together ready for operation using the transfer unit.

First, a first sample holder module 74 of the modular sample holder is provided in an inert shuttle 73 (FIG. 7A). With the aid of the inert shuttle 73, it is possible to provide the first sample holder module 74, which holds the sample (not illustrated), under a protective gas atmosphere.

The inert shuttle 73 loaded in this way is arranged on a flange at the lock chamber 81 (FIG. 7B).

The shuttle valve 82 is opened, such that the first sample holder module 74 can be introduced into the vacuum region using a shuttle rod 76 (FIG. 7C). Meanwhile, the transfer unit 84 is in its rest position, such that the first sample holder module 74 can be introduced undisrupted.

Then the first sample holder module 74 is detachably coupled to the transfer rod 77 of the transfer unit 84 (FIG. 7D).

The first sample holder module 74 is then temporarily brought to an intermediate position by movement of the transfer unit 84 (FIG. 7E). The holding at the intermediate position frees the inert shuttle.

The inert shuttle 73, which is then no longer loaded, is removed from the lock chamber 81 in order to clear the way for further operations (FIG. 7F).

Then the first sample holder module 74 is introduced using the transfer rod 77 of the transfer unit 84 via the now opened lock valve 83 into the sample chamber 71, and positioned in the working position on the sample stage 79 (FIG. 7G). This is effected by handing over the sample holder module 74 to a corresponding receiving apparatus on the sample stage 78.

The transfer rod 77 is then moved back to the rest position. The shuttle valve 82 is closed (FIG. 7H).

The inert shuttle 73 is removed from the lock chamber 81 and stands ready to receive a next object for introduction (FIG. 7I).

Then the inert shuttle 73 is loaded with the second sample holder module 75 (FIG. 7J).

The inert shuttle 73 is again arranged on the flange at the lock chamber 81 (FIG. 7K).

Then the shuttle valve 82 is opened in order to introduce the second sample holder module 75 into the lock chamber 81 using the shuttle rod 76 (FIG. 7L).

In the following step, the second sample holder module 75 is detachably coupled to the transfer rod 77 of the transfer unit 84 (FIG. 7M) and then brought to the parked position by movement of the transfer unit 84 (FIG. 7N).

The inert shuttle 73 is then removed from the lock 72 (FIG. 7O).

Lastly, the second sample holder module 75 is moved using the transfer rod 77 to the working position on the sample stage 79 (FIG. 7P). There it is detachably coupled to the first sample holder module 74.

The transfer unit 84 is then moved to the rest position (FIG. 7Q) and the inert shuttle 73 is removed from the lock chamber 81 (FIG. 7R).

The two sample holder modules 74, 75 are now arranged in their working position, such that the sample processing can be started.

In order to remove the two sample holder modules 74, 75 from their working positions again, the procedure is carried out in reverse order.

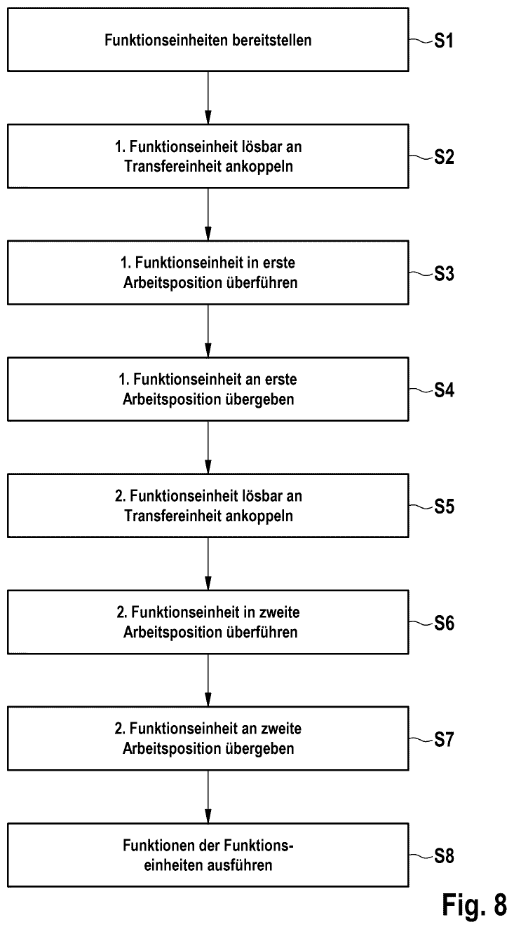

The present disclosure also comprises a method (FIG. 8) for transferring functional units in the vacuum region of a particle beam microscope. The method is carried out using a transfer system comprising a transfer unit and at least a first and a second functional unit, as described above.

The functional units may be designed, for example, as micromanipulators (as described for FIGS. 1A-1E) or sample holders or sensors (as described for FIG. 2A-2E and FIG. 3) or as pressure stage stops.

The transfer system is designed in such a way that the first functional unit is able to be arranged within the vacuum region of the particle beam microscope in a first parked position and in a first working position. Furthermore, the transfer system is designed in such a way that the second functional unit is able to be arranged within the vacuum region of the particle beam microscope in a second parked position and in a second working position.

In a first step S1, the functional units (for example micromanipulators) are provided in the respective parked position. It is desirable for this to be effected in a functional unit changer.

In the next step S2, the first functional unit is detachably coupled to the transfer unit.

In step S3, the first functional unit is transferred from the first parked position to the first working position by movement of the transfer unit.

In principle, the working positions can be located at any location in the vacuum region of the particle beam microscope, for example on any objects, assemblies or surfaces such as the wall of the sample chamber, on the SEM column, the sample holder or the sample stage.

The first functional unit is detached from the transfer unit and handed over to the first working position (S4).

Then (step S5), the second functional unit is detachably coupled to the transfer unit in an analogous manner.

In step S6, the second functional unit is transferred from the second parked position to the second working position by movement of the transfer unit.

Then the second functional unit is detached from the transfer unit and handed over to the second working position (S7).

Further functional units can also be transferred as desired for the respective desired microscopic application.

Lastly, the functions of the functional units are executed (step S8). In the present example of micromanipulators, the microscopic sample is held or moved.

FIG. 9 schematically shows an FIB/SEM combination instrument 90, which is a particle beam microscope that can comprise the transfer system according to the disclosure and can thus be used to carry out the method according to the disclosure.

For this purpose, the FIB/SEM combination instrument 90 has a transfer system, which comprises a transfer unit 112, and multiple functional units 114 which may be designed, for example, as micromanipulators, detectors or sensors. The transfer system also comprises a functional unit changer 115, with the aid of which multiple functional units 114 can be provided in an uncomplicated manner. It is desirable for the transfer system to have receiving apparatuses, these receiving apparatuses and the functional units being modular, such that they are compatible with one another and can be reversibly (i.e. detachably) connected to one another.

A microscopic sample 105 can be provided on a sample holder 104 which is mounted on a sample stage 103. The sample stage 103 is located within the sample chamber 99 of the FIB/SEM combination instrument 90. During operation, vacuum conditions are maintained inside the sample chamber 99.

The sample stage 103 is designed as a multi-axis stage, such that multiple translation and rotation axes are present. An example of such a sample stage is a five-axis stage, which comprises the translation axes x, y, and z and also the rotation axes R and T (tilt). The translation axes are located perpendicularly to one another. Usually, the rotation axis R runs parallel to the z axis, whereas the tilt axis T is located perpendicularly to the rotation axis R.

The FIB/SEM combination instrument 90 comprises two particle beam columns, namely an electron beam column 91 for producing an electron beam and an ion beam column 111 for producing an ion beam. Both particle beams are directed at the microscopic sample 105, which is usually located at the coincidence point of the two particle beams.

During operation of the FIB/SEM combination instrument 90, electrons are produced in an electron source 92. The primary electrons propagate along the optical axis 94 of the electron column 91, are focused by condenser systems 93, 95, parallelized and clipped by at least one stop 96.

In addition, the electron beam column 91 comprises a first deflection system 97, which allows scanning of the primary electron beam over the surface of the sample, and an objective lens system 98. With the aid of the objective lens system 98, the primary beam can be focused on the microscopic sample 105.

Furthermore, the FIB/SEM combination instrument 90 comprises an ion beam column 111 with an ion source 109, a second deflection system 107, a second stop 113, a lens system (FIB) 106 and an objective lens system (FIB) 110. The ion source 109 may, for example, be a liquid metal ion source (LMIS), such as a gallium ion source.

The ions produced in the ion source 109 are accelerated along the optical axis 108 of the ion beam column 111. Then the ion beam is focused and focused on the sample 105 using the objective lens system 110.

With the aid of the ions that are incident on the microscopic sample 105, material can be removed from the sample 105 and/or the sample 105 can be imaged.

Optionally, the FIB/SEM combination instrument 90 may comprise a gas injection system 102 for feeding process gas into the sample chamber 99. The process gas can allow accelerated removal of sample material or the deposition of material onto the sample surface.

Furthermore, the FIB/SEM combination instrument 90 comprises at least one detector 100 for detecting interaction products from the interaction of electrons and/or ions and the material of the microscopic sample 105. The detector 100 may, for example, be an SE detector or a BSE detector for detecting secondary electrons (SE) or backscattered electrons (BSE). However, the detector may also be designed as a detector that detects interaction radiation, such as an EDX detector.

The FIB/SEM combination instrument 90 also comprises an evaluation and control unit 101. The evaluation and control unit 101 can receive and read a computer program product. The computer program product comprises a sequence of control commands which, when executed, cause the particle beam microscope (for example the FIB/SEM combination instrument 90) to carry out the method according to the disclosure.

Optionally, the FIB/SEM combination instrument 90 may also comprise a lock (not illustrated) and/or an inert shuttle (not illustrated), which allow objects or assemblies to be introduced into the vacuum region of the particle beam microscope.

The method according to the disclosure and the transfer system according to the disclosure can not only be used in an FIB/SEM combination instrument. Rather, the particle beam microscope used may also be designed differently, for example as an electron beam microscope in which an electron beam is produced, or an ion beam microscope in which a beam of ions is produced.

### LIST OF REFERENCE SIGNS

1 Sample chamber
2 Sample holder
3 Sample
4 First micromanipulator
5 Second micromanipulator
6 Transfer unit
7 Transfer rod
8 Functional unit changer
9 Lock (optional)
10 Wall
11 Vacuum seal
12 Vacuum region
13 Sample stage
14 First receiving position (first parked position)
15 Second receiving position (first working position)
16 Third receiving position (second parked position)
17 Fourth receiving position (second working position)
14′ First receiving apparatus
15′ Second receiving apparatus
16′ Third receiving apparatus
17′ Fourth receiving apparatus
20 Transfer unit
21 Transfer rod
22 Sensor
23 Lock
24 Lock valve
25 Lock rod
26 Sample holder
27 Sample stage
28 Sample chamber
29 Controller
30 Cable connection
31 Alternative cable connection
32 Receiving apparatus
40 Objective
41 Sample chamber
42 Stop changer (functional unit changer)
43 First pressure stage stop
44 Second pressure stage stop
45 Transfer unit
46 Particle beam column
47 Detector
51 Transfer unit
52 Functional unit changer
53 First functional unit
54 Sample holder
55 Second functional unit
56 Controller
57 Third functional unit
58 Fourth functional unit
59 Lock (optional)
60 Inert shuttle
61 First sample holder
62 Second sample holder
63 Transfer unit
64 Inert shuttle
65 Shuttle valve
66 Lock valve
67 Sample stage
68 Sample chamber
69 Lock
610 First sample holder (with specific sample receptacle)
620 Second sample holder (with standard sample receptacle)
630 Transfer rod
71 Sample chamber
72 Lock
73 Inert shuttle
74 First sample holder module
75 Second sample holder module
76 Shuttle rod
77 Transfer rod
78 Holder receptacle on the sample stage
79 Sample stage
81 Lock chamber
82 Shuttle valve
83 Lock valve
84 Transfer unit
90 FIB/SEM combination instrument
91 Electron beam column
92 Electron source
93 First condenser system
94 Optical axis of the electron beam column
95 Second condenser system
96 Aperture
97 First deflection system
98 Objective lens system (SEM)
99 Sample chamber
100 Detector
101 Evaluation and control unit
102 Gas injection system
103 Sample stage
104 Sample holder
105 Microscopic sample
106 Lens system (FIB)
107 Second deflection system
108 Optical axis of the ion beam column
109 Ion source
110 Objective lens system (FIB)
111 Ion beam column
112 Transfer unit
113 Second stop
114 Functional unit (for example micromanipulator)
115 Functional unit changer
X x axis
Y y axis
Z z axis
R Rotation axis
T Tilt axis
S1 Step: Provide functional units
S2 Step: Detachably couple first functional unit to transfer unit
S3 Step: Transfer first functional unit to first working position
S4 Step: Hand over first functional unit to first working position
S5 Step: Detachably couple second functional unit to transfer unit
S6 Step: Transfer second functional unit to second working position
S7 Step: Hand over second functional unit to second working position
S8 Step: Execute functions of the functional units

What is claimed is:

1. A transfer system configured to transfer functional units in a vacuum region of a particle beam microscope, the transfer system comprising:
a transfer unit;
a first functional unit detachably coupled to the transfer unit; and
a second functional unit detachably coupled to the transfer unit,
wherein:
the first functional unit is configured to execute a function during operation of the particle beam microscope;
the first functional unit is arrangeable in a first position within the vacuum region of the particle beam microscope and in a second position within the vacuum region of the particle beam microscope;
the transfer unit is configured to transfer the first functional unit between the first and second positions;
the second functional unit is configured to execute a function during operation of the particle beam microscope;
the second functional unit is arrangeable in a third position within the vacuum region of the particle beam microscope and in a fourth position within the vacuum region of the particle beam microscope; and
the transfer unit is configured to transfer the second functional unit between the third and fourth positions.

2. The transfer system of 1, wherein the first position is a parked position, the third position is a parked position, the second position is a working position, and the fourth position is a working position.

3. The transfer system of 1, further comprising a first receiving apparatus, a second receiving apparatus, a third receiving apparatus and a fourth receiving apparatus, wherein:
the first functional unit is receivable in the first position via the first receiving apparatus;
the first functional unit is receivable in the second position via the second receiving apparatus;
the second functional unit is receivable in the third position via the third receiving apparatus;
the fourth functional unit is receivable in the second position via the fourth receiving apparatus; and
each of the first and second functional units are able to be handed over between a respective receiving apparatus and the transfer unit.

4. The transfer system of claim 3, wherein each of the first through fourth receiving apparatuses have an identical design.

5. The transfer system of claim 1, wherein the first and second functional units have a substantially identical design.

6. The transfer system of claim 1, wherein a design of the first functional unit is different from a design of the second functional unit.

7. The transfer system of claim 1, wherein the first and second functional units are reversibly couplable to one another.

8. The transfer system of claim 1, further comprising a functional unit changer configured to hold multiple functional units so that they are transferable via the transfer system.

9. The transfer system of claim 1, wherein each of the first and second functional units comprises a member selected from the group consisting of a stop, a micromanipulator, a detector, a sensor, a sample holder, and a sample holder module of a multi-part sample holder.

10. The transfer system of 1, further comprising a first receiving apparatus, a second receiving apparatus, a third receiving apparatus and a fourth receiving apparatus, wherein:
the first is a parked position;
the third position is a parked position;
the second position is a working position;
the fourth position is a working position;
the first functional unit is receivable in the first position via the first receiving apparatus;
the first functional unit is receivable in the second position via the second receiving apparatus;
the second functional unit is receivable in the third position via the third receiving apparatus;
the fourth functional unit is receivable in the second position via the fourth receiving apparatus; and
each of the first and second functional units are able to be handed over between a respective receiving apparatus and the transfer unit.

11. The transfer system of claim 1, wherein the first is a parked position, the third position is a parked position, the second position is a working position, and the fourth position is a working position, the first and second functional units have a substantially identical design.

12. The transfer system of claim 1, wherein the first is a parked position, the third position is a parked position, the second position is a working position, and the fourth position is a working position, and a design of the first functional unit is different from a design of the second functional unit.

13. The transfer system of claim 1, wherein the first is a parked position, the third position is a parked position, the second position is a working position, and the fourth position is a working position, and the first and second functional units are reversibly couplable to one another.

14. The transfer system of claim 1, further comprising a functional unit changer configured to hold multiple functional units so that they are transferable via the transfer system, the first is a parked position, the third position is a parked position, the second position is a working position, and the fourth position is a working position.

15. The transfer system of claim 1, wherein the first is a parked position, the third position is a parked position, the second position is a working position, and the fourth position is a working position, and wherein each of the first and second functional units comprises a member selected from the group consisting of a stop, a micromanipulator, a detector, a sensor, a sample holder, and a sample holder module of a multi-part sample holder.

16. The transfer system of 1, further comprising a first receiving apparatus, a second receiving apparatus, a third receiving apparatus and a fourth receiving apparatus, wherein:
the first is a parked position;
the third position is a parked position;
the second position is a working position;
the fourth position is a working position;
the first functional unit is receivable in the first position via the first receiving apparatus;
the first functional unit is receivable in the second position via the second receiving apparatus;
the second functional unit is receivable in the third position via the third receiving apparatus;
the fourth functional unit is receivable in the second position via the fourth receiving apparatus;
each of the first and second functional units are able to be handed over between a respective receiving apparatus and the transfer unit; and
the first and second functional units have a substantially identical design.

17. The transfer system of 1, further comprising a first receiving apparatus, a second receiving apparatus, a third receiving apparatus and a fourth receiving apparatus, wherein:
the first is a parked position;
the third position is a parked position;
the second position is a working position;
the fourth position is a working position;
the first functional unit is receivable in the first position via the first receiving apparatus;
the first functional unit is receivable in the second position via the second receiving apparatus;
the second functional unit is receivable in the third position via the third receiving apparatus;
the fourth functional unit is receivable in the second position via the fourth receiving apparatus;
each of the first and second functional units are able to be handed over between a respective receiving apparatus and the transfer unit; and
a design of the first functional unit is different from a design of the second functional unit.

18. The transfer system of 1, further comprising a first receiving apparatus, a second receiving apparatus, a third receiving apparatus and a fourth receiving apparatus, wherein:
the first is a parked position;
the third position is a parked position;
the second position is a working position;
the fourth position is a working position;
the first functional unit is receivable in the first position via the first receiving apparatus;
the first functional unit is receivable in the second position via the second receiving apparatus;
the second functional unit is receivable in the third position via the third receiving apparatus;
the fourth functional unit is receivable in the second position via the fourth receiving apparatus;
each of the first and second functional units are able to be handed over between a respective receiving apparatus and the transfer unit; and
the first and second functional units are reversibly couplable to one another.

19. A particle beam microscope, comprising:
a particle beam source configured to generate a particle beam directable at a sample;
a sample chamber enclosing a vacuum region within the particle beam microscope; and
a transfer system according to claim 1.

20. A method, comprising:
coupling a transfer unit with a first functional unit and using the transfer unit to transfer the first functional unit from a first parked position in a vacuum region of a particle beam microscope to a first working position in the vacuum region of the particle beam microscope;
uncoupling the transfer unit from the first functional unit;
coupling the transfer unit with the second functional unit and using the transfer unit to transfer the second functional unit from a second parked position in the vacuum region of the particle beam microscope to a second working position in the vacuum region of the particle beam microscope;
uncoupling the transfer unit from the second functional unit;
using the first functional unit to a function and using the second functional unit to execute a function.
